(19) United States
(12) Patent Application Publication
(10) Pub. No.: US 2024/0297118 A1
(43) Pub. Date: Sep. 5, 2024

(54) SEMICONDUCTOR ELEMENT AND SEMICONDUCTOR DEVICE

(71) Applicant: Rohm Co., Ltd., Kyoto-shi (JP)

(72) Inventor: Hirofumi TANAKA, Kyoto-shi (JP)

(21) Appl. No.: 18/660,903

(22) Filed: May 10, 2024

Related U.S. Application Data
(63) Continuation of application No. PCT/JP2022/040667, filed on Oct. 31, 2022.

(30) Foreign Application Priority Data
Nov. 16, 2021 (JP) 2021-186425

(51) Int. Cl. H01L 23/528; H01L 23/495

(52) U.S. Cl. CPC H01L 23/5283; H01L 23/49513

(57) ABSTRACT

A semiconductor element includes an element body including an obverse surface facing one side in a thickness direction, a wiring layer on the obverse surface electrically connected to the element body, and an obverse-surface electrode formed on and electrically connected to the wiring layer. An outer edge of the obverse-surface electrode includes a corner portion as viewed in the thickness direction. The wiring layer includes a first edge extending along the outer edge of the obverse-surface electrode as viewed in the thickness direction, and a second edge connected to the first edge and facing the corner portion as viewed in the thickness direction. The second edge includes a portion defining, as viewed in the thickness direction, a distance from the second edge to the outer edge of the obverse-surface electrode, wherein the distance is greater than a distance from the first edge to the outer edge of the obverse-surface electrode.

### TECHNICAL FIELD

The present disclosure relates to a semiconductor element and a semiconductor device.

### BACKGROUND ART

Conventionally, semiconductor elements having switching functions have been used for current control in various industrial apparatuses and vehicles. Such a semiconductor element is configured with a switching circuit such as a metal-oxide-semiconductor field-effect transistor (MOSFET) or an insulated gate bipolar transistor (IGBT). For example, JP-A-2020-5323 discloses an example of a semiconductor device including a semiconductor element (MOSFET).

### BRIEF DESCRIPTION OF THE DRAWINGS

FIG. 1 is a perspective view showing a semiconductor device according to an embodiment.

FIG. 2 is a plan view showing the semiconductor device according to the embodiment, with a sealing resin indicated with an imaginary line.

FIG. 3 is a bottom view showing the semiconductor device according to the embodiment.

FIG. 4 is a front view showing the semiconductor device according to the embodiment.

FIG. 5 is a side view showing the semiconductor device according to the embodiment.

FIG. 6 is a cross-sectional view along line VI-VI in FIG. 2.

FIG. 7 is a cross-sectional view along line VII-VII in FIG. 2.

FIG. 8 is a plan view showing a semiconductor element according to the embodiment.

FIG. 9 is a partially enlarged view showing a part of FIG. 8, with (a first portion of) an obverse-surface electrode indicated with an imaginary line and an insulating film omitted.

FIG. 10 is a plan view showing an element body of the semiconductor element according to the embodiment with the obverse-surface electrode and a wiring layer indicated with imaginary lines.

FIG. 11 is a partially enlarged view showing a part of FIG. 10.

FIG. 12 is a cross-sectional view along line XII-XII in FIG. 8, schematically showing the cross-section of the semiconductor element.

FIG. 13 is an enlarged view corresponding to the cross-sectional view of FIG. 12 and showing a main part of the vicinity of a switching circuit.

FIG. 14 is a partially enlarged view showing a part of FIG. 13.

FIG. 15 is a partially enlarged plan view showing a semiconductor element according to a variation, and corresponds to the partially enlarged plan view of FIG. 9.

### DETAILED DESCRIPTION OF EMBODIMENTS

The following describes a preferred embodiment of a semiconductor element and a semiconductor device according to the present disclosure with reference to the drawings. In the following, the same or similar constituent elements are denoted by the same reference numerals, and the descriptions thereof are omitted. The terms such as “first”, “second” and “third” in the present disclosure are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”. Furthermore, the phrase “an object A (or the constituent material thereof) contains a material C” includes “an object A (or the constituent material thereof) is made of a material C” and “an object A (or the constituent material thereof) is mainly composed of a material C”.

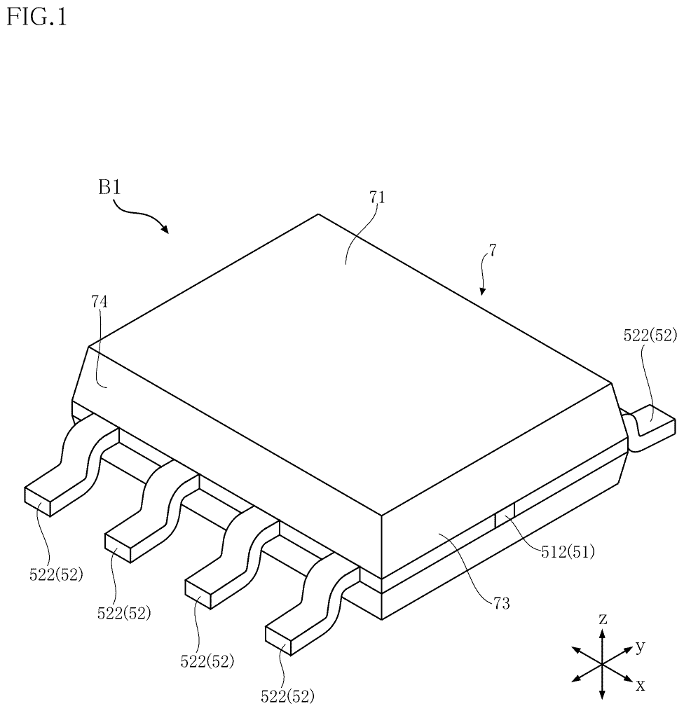

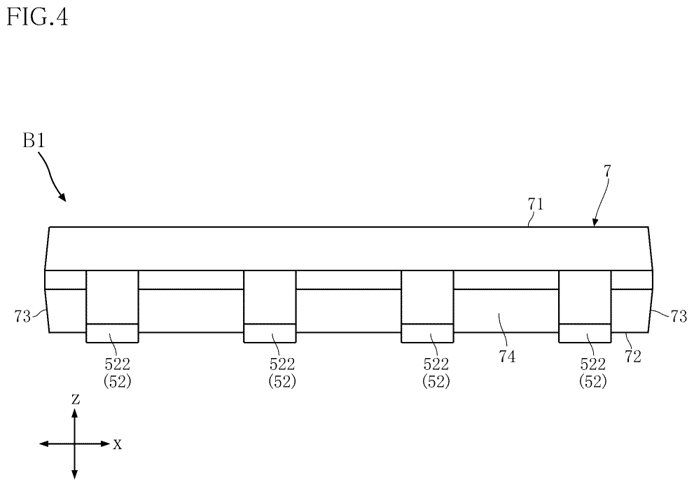

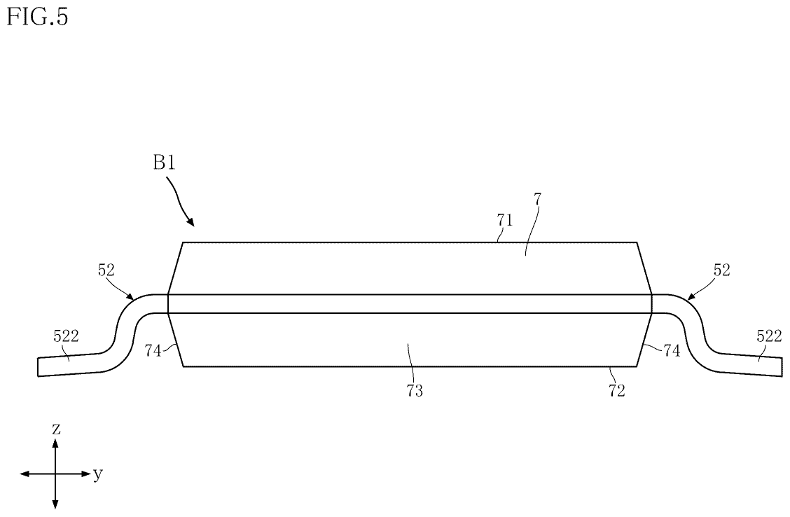

FIGS. 1 to 14 show a semiconductor element A1 according to an embodiment, and a semiconductor device B1 including the semiconductor element A1. As shown in these figures, the semiconductor device B1 includes, in addition to the semiconductor element A1, a first lead 51, a plurality of second leads 52, a plurality of first connecting members 61, a plurality of second connecting members 62, a plurality of third connecting members 63, and a sealing resin 7.

The semiconductor device B1 is an intelligent power device (IPD), for example. As can be understood from the configuration described in detail below, the semiconductor device B1 is configured by modularizing the semiconductor element A1, and the semiconductor element A1 is configured by integrating a power chip, such as a MOSFET or an IGBT, and a control circuit that controls the power chip onto one chip. The shape and size of the semiconductor device B1 is not particularly limited. For example, the semiconductor device B1 has a dimension of 4 mm to 7 mm in a first direction x, a dimension of 4 mm to 8 mm in a second direction y, and a dimension of 0.7 mm to 2.0 mm in a thickness direction z.

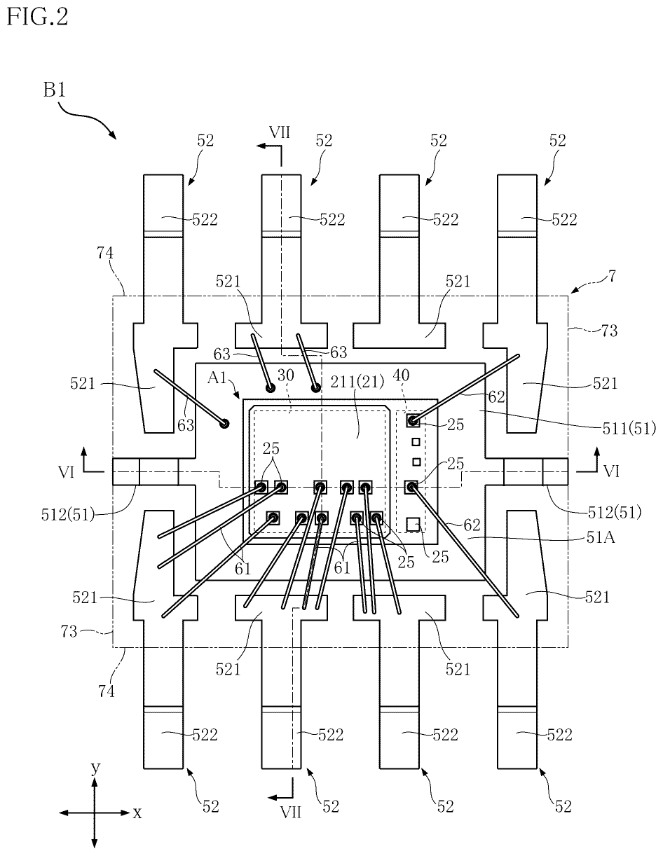

For convenience of description, the thickness direction of the semiconductor device B1 is referred to as the “thickness direction z”. In the following description, one side in the thickness direction z may be referred to as “upward”, and the other side as “downward”. The terms such as “top”, “bottom”, “upward”, “downward”, “upper surface”, and “lower surface” are used to indicate the relative positions of elements and the like in the thickness direction z, and do not necessarily define the relationship with respect to the direction of gravity. Furthermore, “plan view” refers to the view seen in the thickness direction z. A direction perpendicular to the thickness direction z is referred to as the “first direction x”. For example, the first direction x is the horizontal direction in a plan view (see FIG. 2) of the semiconductor device B1. The direction perpendicular to the thickness direction z and the first direction x is referred to as the “second direction y”. The second direction y is the vertical direction in a plan view (see FIG. 2) of the semiconductor device B1.

The semiconductor element A1 exerts the electrical function of the semiconductor device B1. As shown in FIGS. 2, 6, and 7, the semiconductor element A1 is mounted on the first lead 51. The semiconductor element A1 includes an element body 10, an interlayer insulating layer 13, a wiring layer 14, an insulating film 17, an obverse-surface electrode 21, a reverse-surface electrode 24, a plurality of pad portions 25, and a surface protection film 26.

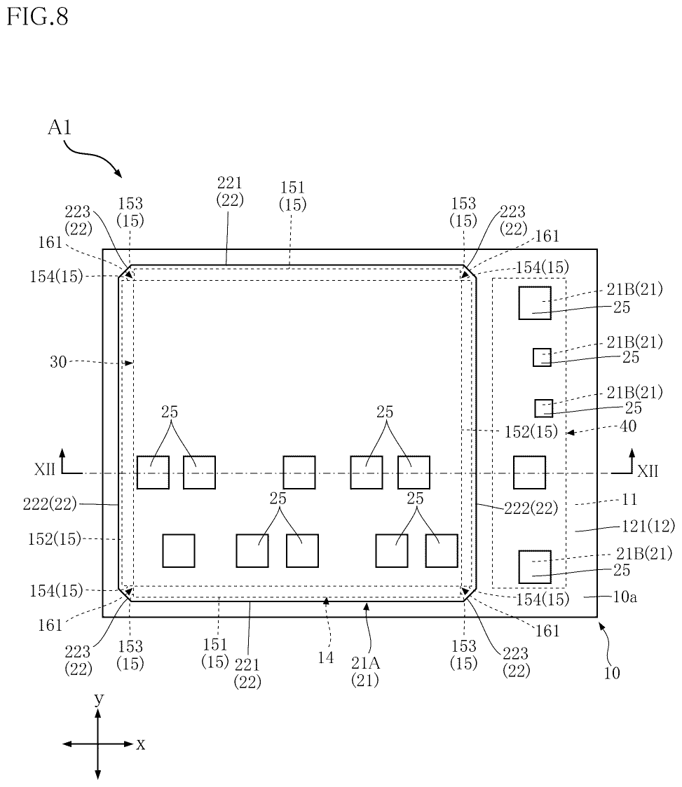

The element body 10 is a main component of the IPD, for example. As shown in FIGS. 2, 8, 10, and 12, the element body 10 includes a switching circuit 30 and a control circuit 40, for example. The switching circuit 30 is a MOSFET or an IGBT, for example. The present embodiment is described with an example where the switching circuit 30 is an n-channel MOSFET having a vertical structure. However, the switching circuit 30 may be a p-channel MOSFET or may have a horizontal structure instead of a vertical structure. Furthermore, the switching circuit 30 may be an IGBT instead of a MOSFET, or may be another transistor. The control circuit 40 controls the switching circuit 30. For example, the control circuit 40 includes functional elements such as a gate drive circuit, a protection circuit, and an active clamp circuit. The gate drive circuit generates a gate signal that controls the drive of the switching circuit 30, based on a control signal inputted from the outside. The protection circuit protects the switching circuit 30 from overcurrent and overheating by detecting, for example, the current flowing through the switching circuit 30 and the temperature of the switching circuit 30. The active clamp circuit absorbs the energy of an inductive load. The functional elements of the control circuit 40 are not limited to the examples given above. The element body 10 may omit the control circuit 40 and may be configured with only the switching circuit 30. The occupancy of each of the switching circuit 30 and the control circuit 40 relative to the element body 10 in plan view is not particularly limited. In the example shown in FIGS. 2 and 8, the occupancy of the switching circuit 30 is larger than that of the control circuit 40.

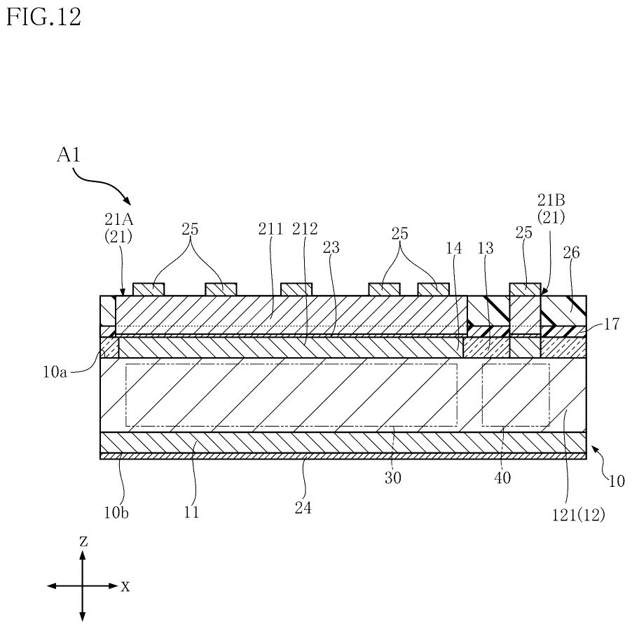

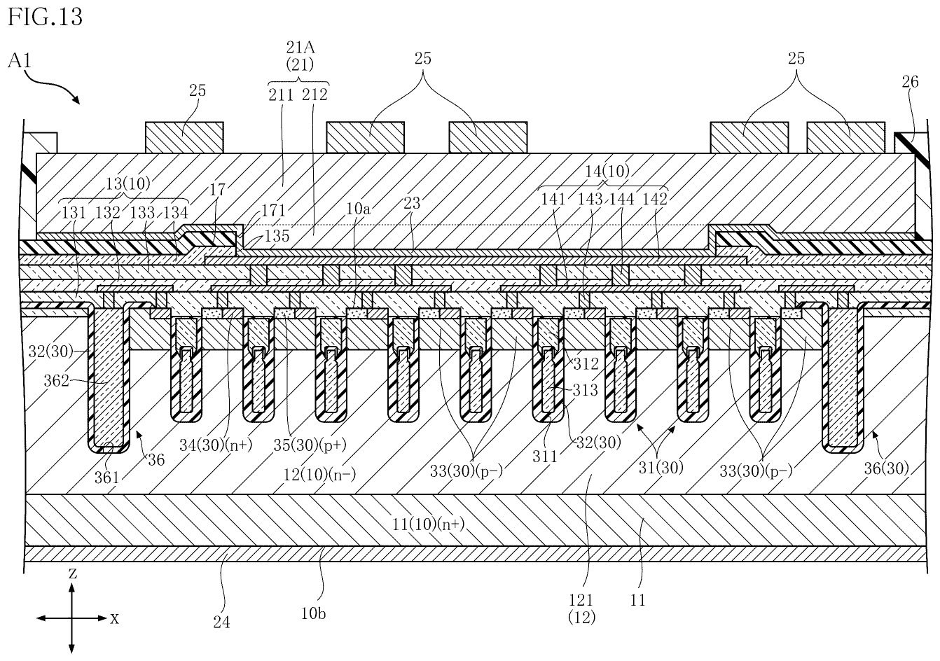

As shown in FIGS. 2 and 8, the element body 10 has a rectangular shape in plan view. As shown in FIG. 12, the element body 10 has an obverse surface 10a and a reverse surface 10b. The obverse surface 10a faces one side in the thickness direction z. The reverse surface 10b faces the opposite side from the obverse surface 10a. As shown in FIGS. 12 and 13, the element body 10 includes a semiconductor substrate 11 and a semiconductor layer 12.

The semiconductor substrate 11 supports the semiconductor layer 12. The semiconductor substrate 11 is an n+ semiconductor layer. The semiconductor substrate 11 contains silicon (Si) or silicon carbide (SiC). The semiconductor substrate 11 has a surface (e.g., the lower surface in FIG. 12) facing away from the semiconductor layer 12 in the thickness direction z, and this surface corresponds to the reverse surface 10b of the element body 10.

The semiconductor layer 12 is formed on the semiconductor substrate 11. As shown in FIG. 12, the switching circuit 30 and the control circuit 40 are configured in the semiconductor layer 12. The semiconductor layer 12 is electrically connected to the semiconductor substrate 11. The boundary surface between the semiconductor layer 12 and each of the interlayer insulating layer 13 and the wiring layer 14 is the obverse surface 10a of the element body 10. The semiconductor layer 12 includes an epitaxial layer 121. The epitaxial layer 121 occupies a large portion of the semiconductor layer 12. The epitaxial layer 121 is an n− semiconductor. The epitaxial layer 121 is formed on the semiconductor substrate 11.

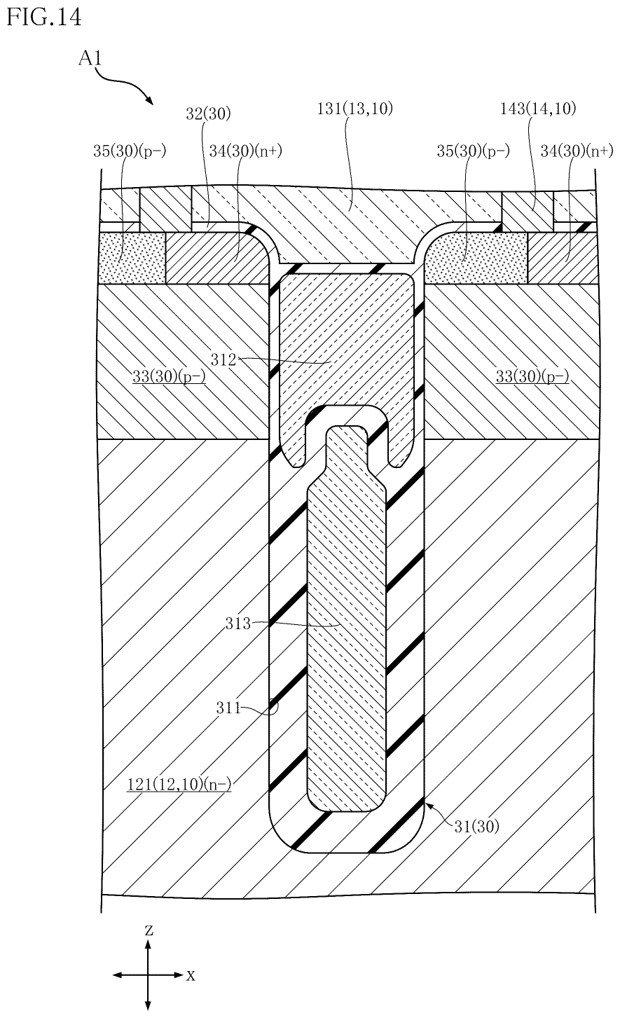

As shown in FIGS. 13 and 14, the switching circuit 30 configured in the semiconductor layer 12 includes a plurality of trench gate structures 31, a gate insulating film 32, a plurality of body regions 33, a plurality of source regions 34, a plurality of body contact regions 35, and a DTI structure 36. Out of these elements, the body regions 33, the source regions 34, and the body contact regions 35 are semiconductors different from the epitaxial layer 121, and are configured by replacing the surface portion of the epitaxial layer 121. The semiconductor layer 12 includes the trench gate structures 31, the gate insulating film 32, the body regions 33, the source regions 34, the body contact regions 35, and the DTI structure 36, in addition to the epitaxial layer 121. The epitaxial layer 121 and the semiconductor substrate 11 constitute the drain region of the switching circuit 30.

As shown in FIGS. 13 and 14, the trench gate structures 31 extend from the boundary surface between each of the body regions 33 and each of the source regions 34 and the body contact regions 35 in the thickness direction z toward the semiconductor substrate 11. The trench gate structures 31 are arranged at equal intervals in the first direction x and extend in the second direction y. As shown in FIGS. 13 and 14, each of the trench gate structures 31 has a first trench 311, a gate electrode 312, and an embedded electrode 313.

The first trench 311 forms a groove dug from the boundary surface between each of the body regions 33 and each of the source regions 34 and the body contact regions 35 in the thickness direction z toward the semiconductor substrate 11. The gate electrode 312 and the embedded electrode 313 are spaced apart from each other in the thickness direction z and housed in the first trench 311. The embedded electrode 313 is located closer to the semiconductor substrate 11 than is the gate electrode 312 in the thickness direction z. The gate electrode 312 and the embedded electrode 313 are polycrystalline polysilicon, for example. The gate electrode 312 and the embedded electrode 313 extend in the second direction y.

Each of the first trenches 311 has the gate insulating film 32 embedded therein. The gate electrode 312 and the embedded electrode 313 are covered with the gate insulating film 32. The gate insulating film 32 is silicon oxide (SiO₂), for example. The gate insulating film 32 electrically insulates the gate electrode 312 and the embedded electrode 313 from each other. The gate insulating film 32 also electrically insulates the gate electrode 312 and the embedded electrode 313 from the outside of the trench gate structure 31.

The body regions 33 are formed on the epitaxial layer 121. The body regions 33 are p− semiconductors. The body regions 33 extend in the second direction y. Each of the body regions 33, except for those located at both ends in the first direction x, is sandwiched by two of the trench gate structures 31 that are adjacent to each other in the first direction x. The body regions 33 each sandwiched by two adjacent trench gate structures 31 in the first direction x include a body region 33 that is in contact with the gate insulating film 32 embedded in each of the two trench gate structures 31.

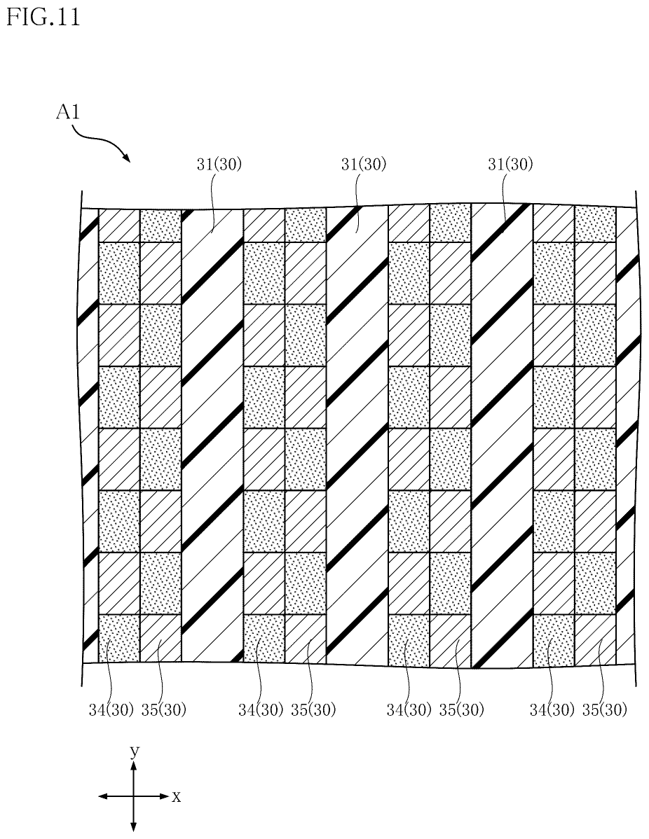

As shown in FIGS. 13 and 14, the source regions 34 and the body contact regions 35 are formed on the body regions 33. The source regions 34 are n+ semiconductors. The body contact regions 35 are p+ semiconductors. In each of the trench gate structures 31 in a cross section perpendicular to the second direction y, one of the source regions 34 adjoins one side of the trench gate structure 31 in the first direction x, and one of the body contact regions 35 adjoins the other side of the trench gate structure 31 in the first direction x. As shown in FIG. 11, in the region sandwiched by two adjacent trench gate structures 31 of the plurality of trench gate structures 31 in plan view, the source regions 34 and the body contact regions 35 are in contact with each other in the first direction x and arranged alternately in the second direction y. Accordingly, the source regions 34 and the body contact regions 35 form a checkered pattern in the region (see FIG. 11). The source regions 34 and the body contact regions 35 are covered with the gate insulating film 32. The body contact regions 35 can be replaced with the body regions 33 that are p-type semiconductors.

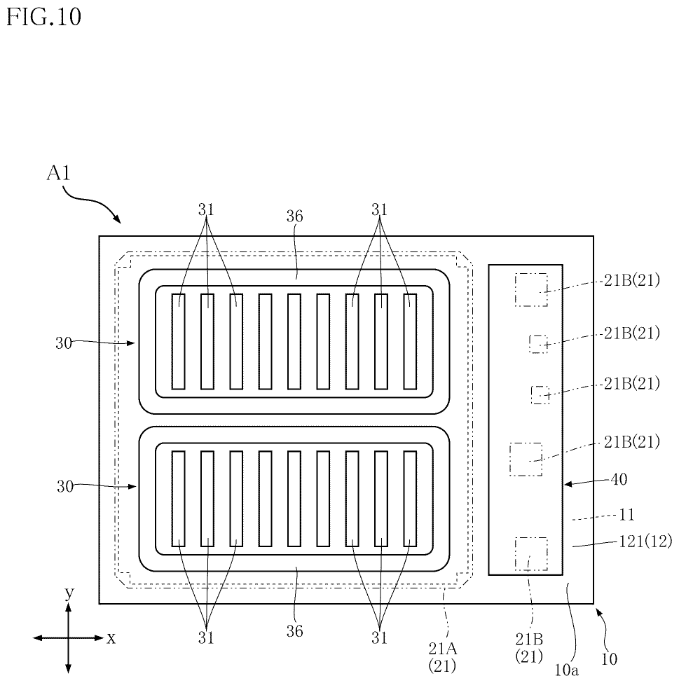

As shown in FIG. 13, the DTI structure 36 (DTI: Deep Trench Isolation) extends from the boundary surface between the epitaxial layer 121 and the interlayer insulating layer 13 in the thickness direction z toward the semiconductor substrate 11. The bottom of the DTI structure 36 is positioned closer to the semiconductor substrate 11 than the bottom of each trench gate structure 31. The DTI structure 36 has a frame shape surrounding the trench gate structures 31 in plan view. Thus, as shown in FIG. 10, the switching circuit 30 is partitioned from the control circuit 40 by the DTI structure 36. In the illustrated example, the switching circuit 30 is partitioned into two regions by two DTI structures 36. However, the switching circuit 30 may be partitioned into three or more regions by three or more DTI structures 36, or may be grouped as a single region and partitioned from the control circuit 40 by a single DTI structure 36. The semiconductor element A1 is described with an example where the DTI structure 36 is used as a means to partition the switching circuit 30. However, it is possible to use a p-type diffusion region, which is formed by replacing a portion of the epitaxial layer 121, as another such means. As shown in FIG. 13, the DTI structure 36 has a second trench 361 and an insulator 362.

The second trench 361 forms a groove dug from the boundary surface between the epitaxial layer 121 and the interlayer insulating layer 13 in the thickness direction z toward the semiconductor substrate 11. The insulator 362 is accommodated in the second trench 361. The insulator 362 may be polycrystalline polysilicon or silicon oxide. The second trench 361 has the gate insulating film 32 embedded therein. The insulator 362 is covered with the gate insulating film 32.

The interlayer insulating layer 13 is stacked on the semiconductor layer 12 and formed on the obverse surface 10a. The interlayer insulating layer 13 contains at least one of silicon oxide and silicon nitride (Si₃N₄). The interlayer insulating layer 13 is formed by plasma chemical vapor deposition (CVD), for example.

As shown in FIG. 13, the interlayer insulating layer 13 has a first film 131, a second film 132, a third film 133, and a fourth film 134. The first film 131 is stacked on the gate insulating film 32. As shown in FIGS. 13 and 14, the trench gate structures 31 are formed with a plurality of dents each resulting from a step between a gate electrode 312 and a group of source regions 34 and body contact regions 35 in the thickness direction z. The first film 131 enters each of the dents. The second film 132 is stacked on the first film 131. The third film 133 is stacked on the second film 132. The fourth film 134 is stacked on the third film 133. As shown in FIG. 13, the fourth film 134 is formed with a plurality of openings 135 passing through in the thickness direction z. A portion of the wiring layer 14 is exposed from each of the openings 135. The openings 135 are connected to a plurality of openings 171 (described below) in the insulating film 17. The position and size of each opening 135 corresponds to the position and size of each opening 171 in the insulating film 17.

The wiring layer 14 is stacked on the semiconductor layer 12 and formed on the obverse surface 10a. The wiring layer 14 contains aluminum (Al), for example. The wiring layer 14 may be made of an aluminum-copper (Cu) alloy (AlCu).

As shown in FIG. 13, the wiring layer 14 includes a first layer 141, a second layer 142, a plurality of first vias 143, and a plurality of second vias 144. The first layer 141 and the second layer 142 are stacked and spaced apart from each other in the thickness direction z with the interlayer insulating layer 13 interposed therebetween. The first layer 141 is formed on the first film 131 and covered with the second film 132. The second layer 142 is formed on the third film 133. The periphery of the second layer 142 is covered with the fourth film 134 in plan view. The portions of the second layer 142 not covered with the fourth film 134 are exposed from the openings 135 in the fourth film 134 and openings 171 (described below) of the insulating film 17, and the exposed portions are covered with an underlying layer 23. The first vias 143 are embedded in the first film 131, and pass through the first film 131 in the thickness direction z. The first vias 143 are connected to the first layer 141, the source regions 34, and the body contact regions 35. The second vias 144 are embedded in the second film 132 and the third film 133, and pass through the third film 133 and the second film 132 arranged on the first layer 141 in the thickness direction z. Each of the second vias 144 is connected to the first layer 141 and the second layer 142. In the illustrated example, the wiring layer 14 is made up of two layers, namely the first layer 141 and the second layer 142. However, the wiring layer 14 may be made up of a single layer or three or more layers. Each of the first layer 141 and the second layer 142 may have a thickness (i.e., the dimension in the thickness direction z) of 0.1 μm to 4.0 μm.

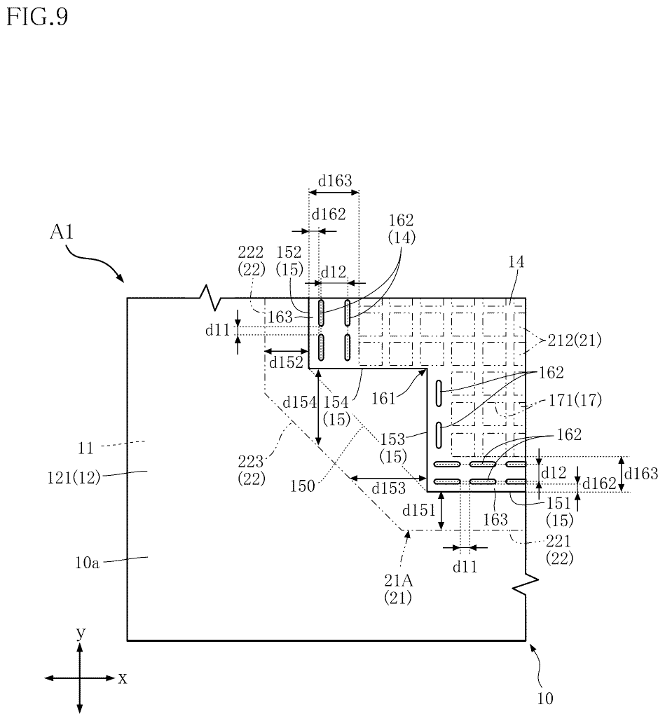

As shown in FIGS. 8 and 9, an outer edge 15 of the wiring layer 14 in plan view has a plurality of first edges 151 and 152 and a plurality of second edges 153 and 154. The outer edge 15 (the first edges 151 and 152 and the second edges 153 and 154) is the periphery of each of the first layer 141 and the second layer 142 in the wiring layer 14 in plan view.

Each of the first edges 151 and 152 extends along an outer edge 22 (described below) of the obverse-surface electrode 21 in plan view. A pair of first edges 151 extend in the first direction x and are spaced apart from each other in the second direction y. A pair of first edges 152 extend in the second direction y and are spaced apart from each other in the first direction x.

Each of the second edges 153 and 154 is connected to one of the first edges 151 and 152. Each of the second edges 154 extends in the first direction x, and each of the second edges 153 extends in the second direction y. In the example shown in FIGS. 8 and 9, the second edges 153 and the second edges 154 are perpendicular to each other. Furthermore, the second edges 153 are perpendicular to the first edges 151, and the second edges 154 are perpendicular to the first edges 152. Unlike this example, the second edges 153 may be inclined to the first edges 151, and the second edges 154 may be inclined to the first edges 152.

As shown in FIGS. 8 and 9, the wiring layer 14 has a plurality of cutouts 161, a plurality of slits 162, and an edge portion 163.

The cutouts 161 are provided at four corners of the rectangular wiring layer 14 defined by the first edges 151 and 152. Each of the cutouts 161 has an L shape in plan view, and has a pair of second edges 153 and 154 among the above-described second edges 153 and 154. Each pair of second edges 153 and 154 is formed by a cutout 161.

The edge portion 163 is a portion of the wiring layer 14 located between a portion of the obverse-surface electrode 21 (a plurality of penetrating portions 212 described below) and each of the first edges 151 and 152 in plan view. The edge portion 163 is arranged along the outer edge 15.

The slits 162 are where the wiring layer 14 (at least the second layer 142) is not formed. The slits 162 are arranged appropriately at the edge portion 163. In the example shown in FIG. 9, the slits 162 include those arranged along the first edges 151, those arranged along the first edges 152, and those arranged along the second edges 153. In the example shown in FIG. 9, the slits 162 are arranged in two rows along each of the first edges 151 and 152. The number of rows of the slits 162 is changed appropriately according to a distance d163 (see FIG. 9) between the outer edge 22 and openings 171 (penetrating portions 212 described below). Although the slits 162 are arranged to form a neatly aligned matrix pattern in the example shown in FIG. 9, they may be arranged otherwise to form an irregularly deformed pattern. Each slit 162 has a strip shape in plan view in the illustrated example, but the plan-view shape of each slit 162 is not particularly limited. For example, the plan-view shape of each slit 162 may be a circle, a polygon, or an ellipse, instead of a strip. The plan-view dimensions of each slit 162 are not particularly limited. In the case where each slit 162 has a strip shape, the dimension thereof in the longitudinal direction is 0.5 μm to 10 μm (e.g., 4.8 μm), and the dimension thereof in the transverse direction is 0.5 μm to 10 μm (e.g., 1.2 μm). A distance d11 (see FIG. 9) between any two of the slits 162 is 0.5 μm to 3.0 μm, for example. A distance d12 (see FIG. 9) between any two of the rows of the slits 162 is 0.5 μm to 3.0 μm, for example. A distance d162 (see FIG. 9) from the slits 162 arranged along each of the pairs of first edges 151 and 152 to each of the pairs of first edges 151 and 152 is 0.1 μm to 2.0 μm, for example.

The insulating film 17 is stacked on the interlayer insulating layer 13. The insulating film 17 is electrically insulative, and may be a passivation film. The insulating film 17 may contain silicon nitride. Unlike this configuration, the insulating film 17 may be made up of a silicon oxide film formed on the interlayer insulating layer 13 and a silicon nitride film formed on the silicon oxide film. As shown in FIG. 13, the insulating film 17 is formed with a plurality of openings 171 passing through in the thickness direction z. The openings 171 are spaced apart from each other in plan view. The openings 171 are connected to the respective openings 135, and a portion of the wiring layer 14 is exposed from each of the openings 171 and the openings 135. As shown in FIG. 9, openings 171 near each of the four corners of the wiring layer 14 are arranged in an L shape in plan view.

The obverse-surface electrode 21 is formed on the wiring layer 14. The obverse-surface electrode 21 is made of a metal material and may contain copper. The obverse-surface electrode 21 includes a first portion 21A and a second portion 21B. The first portion 21A and the second portion 21B are spaced apart from each other. The first portion 21A overlaps with the switching circuit 30 in plan view, and is electrically connected to the switching circuit 30 via the underlying layer 23 and the wiring layer 14. The second portion 21B overlaps with the control circuit 40, and is electrically connected to the control circuit 40 via the underlying layer 23 and the wiring layer 14.

As shown in FIGS. 12 and 13, the obverse-surface electrode 21 (each of the first portion 21A and the second portion 21B) includes a main portion 211 and a plurality of penetrating portions 212.

The main portion 211 is formed on the insulating film 17. The thickness (the dimension in the thickness direction z) of the main portion 211 may be, but not limited to, 100% to 2000% with respect to the thickness of each of the first layer 141 and the second layer 142. In the example where the thickness of each of the first layer 141 and the second layer 142 is 0.1 μm to 4.0 μm, the thickness (the dimension in the thickness direction z) of the main portion 211 may be 4.0 μm to 20.0 μm.

The penetrating portions 212 are each connected to the main portion 211. The penetrating portions 212 are integrally formed with the main portion 211. The penetrating portions 212 fill the respective openings 171. The penetrating portions 212 are embedded in the insulating film 17 and pass through the insulating film 17 in the thickness direction z. Each of the penetrating portions 212 is connected to a portion of the wiring layer 14 exposed from one of the openings 171, via the underlying layer 23. Each of the penetrating portions 212 electrically connects the main portion 211 and the wiring layer 14.

As shown in FIG. 8, the outer edge 22 of the obverse-surface electrode 21 (the first portion 21A in the illustrated example) has an octagonal shape in plan view, for example. The plan-view shape of the outer edge 22 is not limited to an octagon. As shown in FIG. 8, the outer edge 22 surrounds the outer edge 15 of the wiring layer 14 in plan view. The outer edge 22 corresponds to the periphery of the main portion 211 in plan view. As shown in FIGS. 8 and 9, the outer edge 22 has a plurality of side ends 221 and 222, and a plurality of corner portions 223.

The side ends 221 and 222 are connected to each other via the corner portions 223. A pair of side ends 221 extend in the first direction x and are spaced apart from each other in the second direction y. A pair of side ends 222 extend in the second direction y and are spaced apart from each other in the first direction x.

The corner portions 223 are arranged at four corners of the obverse-surface electrode 21 when the obverse-surface electrode 21 defined by the side ends 221 and 222 is seen as a rectangle in plan view. Each of the corner portions 223 is connected to one of the pair of side ends 221 and one of the pair of side ends 222. Each corner portion 223 is linear in plan view and inclined to the two side ends 221 and 222 connected to the corner portion 223.

As shown in FIGS. 8 and 9, the semiconductor element A1 is configured such that the outer edge 15 of the wiring layer 14 and the outer edge 22 of the obverse-surface electrode 21 have the following relationships.

First, the first edges 151 and the side ends 221 are substantially parallel to each other. For example, in plan view, a distance d151 (see FIG. 9) between a first edge 151 to the outer edge 22 (a side end 221), i.e., the interval between the first edge 151 and the side end 221, in the vertical direction (the second direction y in FIG. 9) of the first edge 151, is 5.0 μm to 20 μm. Similarly, the first edges 152 and the side ends 222 are parallel (or substantially parallel) to each other. For example, in plan view, a distance d152 (see FIG. 9) between a first edge 152 to the outer edge 22 (a side end 222), i.e., the interval between the first edge 152 and the side end 222, in the vertical direction (the first direction x in FIG. 9) of the first edge 152, is 5.0 μm to 20 μm. Although the distance d151 and the distance d152 are the same (or substantially the same) in the present embodiment, they may be different from each other.

Second, each of the second edges 153 includes a portion where a distance d153 (see FIG. 9) from the second edge 153 to the outer edge 22 (a corner portion 223) in the vertical direction (the first direction x in the example shown in FIG. 9) of the second edge 153 is greater than the distance d151. In the example shown in FIG. 9, the distance d153 is greater than the distance d151 at any position on the second edge 153. Similarly, each of the second edges 154 includes a portion where a distance d154 (see FIG. 9) from the second edge 154 to the outer edge 22 (a corner portion 223) in the vertical direction (the second direction y in the example shown in FIG. 9) of the second edge 154 is greater than the distance d152. In the example shown in FIG. 9, the distance d154 is greater than the distance d152 at any position on the second edge 154. In the following description, these relationships may be referred to as “second relationships”.

As shown in FIGS. 12 and 13, the underlying layer 23 is arranged under the obverse-surface electrode 21, and is in contact with the obverse-surface electrode 21. The underlying layer 23 contains titanium (Ti), for example.

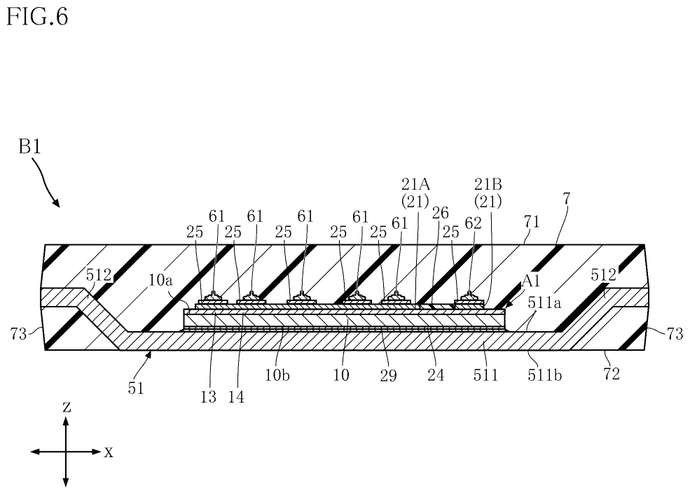

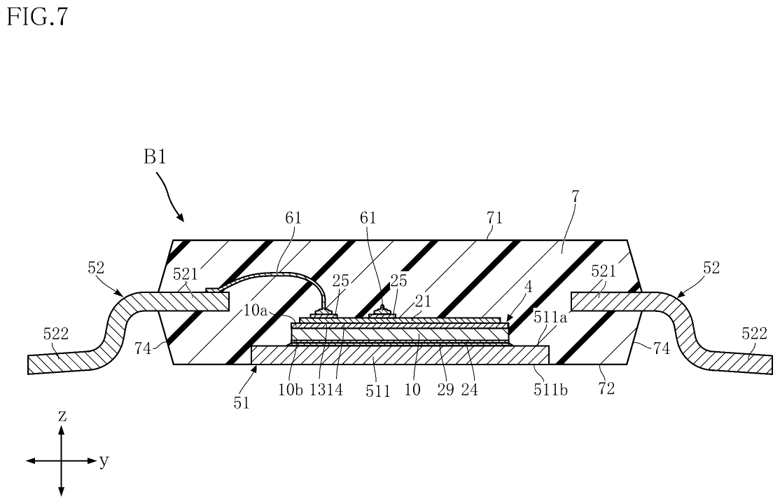

As shown in FIGS. 6, 7, 12, and 13, the reverse-surface electrode 24 is provided at the reverse surface 10b of the element body 10. The reverse-surface electrode 24 is provided over the entirety of the reverse surface 10b. The reverse-surface electrode 24 is electrically connected to the semiconductor layer 12 (epitaxial layer 121) via the semiconductor substrate 11. The material and configuration of the reverse-surface electrode 24 are not particularly limited. For example, the reverse-surface electrode 24 may include a layer that is in contact with the semiconductor substrate 11 and contains silver (Ag), and a layer that is formed on the Ag layer and contains gold (Au). As shown in FIGS. 6 and 7, the reverse-surface electrode 24 is bonded to the first lead 51 via a conductive bonding member 29. The material of the conductive bonding member 29 may be, but not limited to, solder, silver paste, or sintered silver.

The pad portions 25 are formed on the main portion 211 of the obverse-surface electrode 21. The pad portions 25 include those formed on the first portion 21A and those formed on the second portion 21B. The pad portions 25 are formed to facilitate bonding of the first connecting members 61 and the second connecting members 62 with respect to the obverse-surface electrode 21. Unlike the illustrated example, the semiconductor element A1 may not include any of the pad portions 25, and the first connecting members 61 and the second connecting members 62 may be directly bonded to the obverse-surface electrode 21. The configuration and material of the pad portions 25 are not particularly limited. For example, each of the pad portions 25 may include a nickel (Ni) layer, a palladium (Pd) layer, and a Au layer stacked in this order from the side that is in contact with the obverse-surface electrode 21.

As shown in FIGS. 12 and 13, the surface protection film 26 covers a surface of the insulating film 17. The surface protection film 26 covers a side surface of the main portion 211 of the obverse-surface electrode 21. The surface protection film 26 is electrically insulative. The surface protection film 26 contains polyimide, for example.

The first lead 51 and the second leads 52 are each made of a metal selected from a group including Cu, Ni, and iron (Fe) or an alloy thereof, for example. Appropriate portions of the first lead 51 and the second leads 52 may be plated with a metal selected from a group including Ag, Ni, Pd, and Au. The thickness of each of the first lead 51 and the second leads 52 is not particularly limited, and may be 0.12 mm to 0.2 mm.

The first lead 51 supports the semiconductor element A1. The first lead 51 is electrically connected to the reverse-surface electrode 24 of the semiconductor element A1 via the conductive bonding member 29. As shown in FIGS. 2, 6, and 7, the first lead 51 has a die pad portion 511 and two extending portions 512.

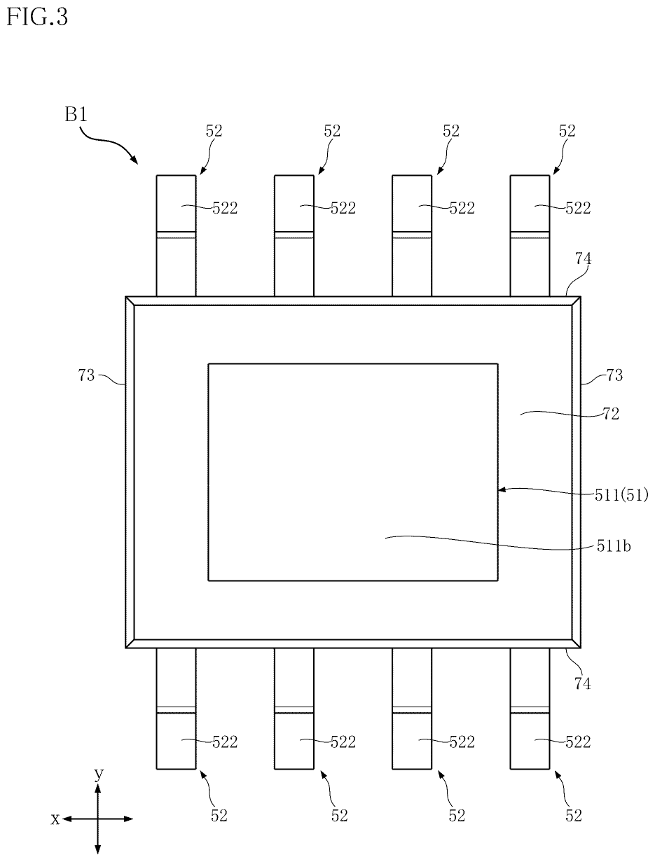

The die pad portion 511 supports the semiconductor element A1. The shape of the die pad portion 511 is not particularly limited. In the example shown in FIG. 2, the die pad portion 511 has a rectangular shape in plan view. As shown in FIGS. 6 and 7, the die pad portion 511 has a die-pad obverse surface 511a and a die-pad reverse surface 511b. The die-pad obverse surface 511a faces a first side in the thickness direction z. The die-pad reverse surface 511b faces away from the die-pad obverse surface 511a in the thickness direction z. In the illustrated example, the die-pad obverse surface 511a and the die-pad reverse surface 511b are flat surfaces. The semiconductor element A1 is bonded to the die-pad obverse surface 511a. As shown in FIGS. 3, 6, and 7, the die-pad reverse surface 511b is exposed from the sealing resin 7 (a resin reverse surface 72 described below).

As shown in FIGS. 2 and 6, the two extending portions 512 extend from the die pad portion 511 to the respective sides in the first direction x. In the example shown in FIG. 6, each of the extending portions 512 has a first section extending from the die pad portion 511 in the first direction x, a second section inclined relative to the first section and extending to the side in the thickness direction z that the die-pad obverse surface 511a faces, and a third section extending from the second section in the first direction x, so that the extending portion 512 has a bent shape as a whole.

As shown in FIG. 2, the second leads 52 are spaced apart from the first lead 51. The second leads 52 include those electrically connected to the switching circuit 30 and those electrically connected to the control circuit 40. The second leads 52 are arranged around the first lead 51. In the illustrated example, the second leads 52 include those arranged on a first side in the second direction y with respect to the first lead 51, and those arranged on a second side in the second direction y with respect to the first lead 51. The second leads 52 on each of the first side and the second side in the second direction y are spaced apart from each other in the first direction x. As shown in FIGS. 2 and 6, each of the second leads 52 has a pad portion 521 and a terminal portion 522.

One of the first connecting members 61, the second connecting members 62, and the third connecting members 63 is connected to the pad portion 521. In the example shown in FIG. 7, the pad portion 521 is offset from the die pad portion 511 to the side in the thickness direction z that the die-pad obverse surface 511a faces.

The terminal portion 522 extends outward from the pad portion 521 in the second direction y. The terminal portion 522 has a strip shape in plan view. As shown in FIG. 7, the terminal portion 522 is bent into a gull-wing shape as viewed in the first direction x. As shown in FIG. 7, a tip (an end distal to the die pad portion 511 in the second direction y) of the terminal portion 522 is located at the same (or substantially the same) position as the die pad portion 511 in the thickness direction z.

The terminal portions 522 of the second leads 52 are used as external terminals of the semiconductor device B1. The external terminals include an input terminal for a control signal, a ground terminal, an output terminal connected to a load, a power supply terminal, a non-connected terminal, a self-diagnostic output terminal.

Each of the first connecting members 61, the second connecting members 62, and the third connecting members 63 electrically connects two elements that are spaced apart from each other. The first connecting members 61, the second connecting members 62, and the third connecting members 63 are bonding wires, for example. The first connecting members 61, the second connecting members 62, and the third connecting members 63 may be plate-like metal members instead of bonding wires. Each of the first connecting members 61, the second connecting members 62, and the third connecting members 63 may contain a metal selected from a group including Au, Cu, and Al.

Each of the first connecting members 61 is bonded to one of the pad portions 25 formed on the first portion 21A of the semiconductor element A1 and one of the pad portions 521 of the second leads 52. Each of the first connecting members 61 electrically connects the obverse-surface electrode 21 (first portion 21A) and one of the second leads 52.

Each of the second connecting members 62 is bonded to one of the pad portions 25 formed on the second portion 21B of the semiconductor element A1 and one of the pad portions 521 of the second leads 52. Each of the second connecting members 62 electrically connects the obverse-surface electrode 21 (second portion 21B) and one of the second leads 52.

Each of the third connecting members 63 is bonded to the die pad portion 511 and one of the pad portions 521 of the second leads 52. Each of the third connecting members 63 electrically connects the reverse-surface electrode 24 and one of the second leads 52.

The sealing resin 7 covers a portion of each of the first lead 51 and the second leads 52, the semiconductor element A1, the first connecting members 61, the second connecting members 62, and the third connecting members 63. The sealing resin 7 is an insulating resin, and may contain an epoxy resin mixed with a filler. The sealing resin 7 has a resin obverse surface 71, a resin reverse surface 72, two resin side surfaces 73, and two resin side surfaces 74.

The resin obverse surface 71 faces the same side as the die-pad obverse surface 511a in the thickness direction z. The resin obverse surface 71 is a flat surface, for example. The resin reverse surface 72 faces the opposite side from the resin obverse surface 71 (the same side as the die-pad reverse surface 511b) in the thickness direction z. The resin reverse surface 72 is a flat surface, for example. The die-pad reverse surface 511b is exposed from the resin reverse surface 72.

The two resin side surfaces 73 are located between the resin obverse surface 71 and the resin reverse surface 72 in the thickness direction z, and are spaced apart from each other in the first direction x as shown in FIGS. 2 to 4. Each of the extending portions 512 is exposed from one of the two resin side surfaces 73. The two resin side surfaces 74 are located between the resin obverse surface 71 and the resin reverse surface 72 in the thickness direction z, and are spaced apart from each other in the second direction y as shown in FIGS. 2, 3 and 5. Each of the second leads 52 protrudes from one of the two resin side surfaces 74.

The following describes the advantages of the semiconductor element A1 and the semiconductor device B1.

The semiconductor element A1 includes the wiring layer 14 formed on the obverse surface 10a of the element body 10, and the obverse-surface electrode 21 formed on the wiring layer 14. In this configuration, when the temperature of the semiconductor element A1 rises, the wiring layer 14 is subjected to a stress (thermal stress) via the insulating film 17 due to the thermal expansion of the obverse-surface electrode 21. If the semiconductor element A1 has a different configuration whereby, in plan view, a portion of the outer edge 15 of the wiring layer 14 connected to a pair of first edges 151 and 152 corresponds to a virtual edge 150 shown in FIG. 9, then portions near the four corners of the wiring layer 14 may be crushed and deformed as a result of the thermal stress applied to the wiring layer 14. Note that the distance from the virtual edge 150 to the outer edge 22 (corner portion 223) in the direction vertical to the virtual edge 150 is the same (or substantially the same) as each of the distances d151 and d152 shown in FIG. 9. The deformation of the wiring layer 14 as described above may cause breakage of the wiring layer 14, and may also cause a void between the wiring layer 14 and the insulating film 17 when the temperature of the semiconductor element A1 drops to a normal temperature. In other words, deformation of the wiring layer 14 lowers the reliability of the semiconductor element. In view of this, the semiconductor element A1 is configured such that the outer edge 15 of the wiring layer 14 includes a pair of second edges 153 and 154 connected to a pair of first edges 151 and 152. Further, each of the second edges 153 and 154 includes a portion that defines, in plan view, a distance d153 or d154 between the second edge 153 or 154 and the outer edge 22 (corner portion 223) of the obverse-surface electrode 21 along the direction perpendicular to the second edge 153 or 154, where the distance d153 or d154 is greater than the distance d151 or d152 between the first edge 151 or 152 and the outer edge 22 of the obverse-surface electrode 21 along the direction perpendicular to the first edge 151 or 152. In other words, the semiconductor element A1 is configured such that the wiring layer 14 and the obverse-surface electrode 21 satisfy the second relationships described above. As a result, the semiconductor element A1 allows the portion of the wiring layer 14 arranged in a uniform manner to have a relatively small area at the four corners of the wiring layer 14 in plan view, as compared to the configuration where the portion of the outer edge 15 connected to a pair of first edges 151 and 152 corresponds to the virtual edge 150 in FIG. 9. This makes it possible to reduce the occurrence of breakage of the wiring layer 14 and voids between the wiring layer 14 and the insulating film 17 by suppressing the thermal stress applied to the wiring layer 14 by the thermal expansion of the obverse-surface electrode 21. In other words, the semiconductor element A1 can improve reliability on a temperature change.

In the semiconductor element A1, the obverse-surface electrode 21 contains copper and the wiring layer 14 contains aluminum. In such a configuration, the difference in coefficients of thermal expansion between the obverse-surface electrode 21 and the wiring layer 14 causes the thermal stress due to the thermal expansion of the obverse-surface electrode 21 to be easily applied to the wiring layer 14. Accordingly, as can be seen in the semiconductor element A1, configuring the wiring layer 14 and the obverse-surface electrode 21 to satisfy the second relationships described above is preferable in terms of improving the reliability of the semiconductor element A1 on a temperature change.

In the semiconductor element A1, the thickness (the dimension in the thickness direction z) of the main portion 211 of the obverse-surface electrode 21 is 100% to 2000% with respect to the thickness (the dimension in the thickness direction z) of each of the first layer 141 and the second layer 142 of the wiring layer 14. Although an increase in the size of the obverse-surface electrode 21 enables a decrease in the on-resistance of the switching circuit 30, it also causes an increase in the thermal stress on the wiring layer 14 due to the thermal expansion of the obverse-surface electrode 21. In view of this, the thickness of the main portion 211 is designed to be 100% to 2000% with respect to the thickness of each of the first layer 141 and the second layer 142, and the wiring layer 14 and the obverse-surface electrode 21 are configured to satisfy the second relationships described above, whereby the semiconductor element A1 can improve reliability on a temperature change while reducing the on-resistance of the switching circuit 30.

In the semiconductor element A1, the wiring layer 14 includes the cutouts 161 each having a pair of second edges 153 and 154. Each of the cutouts 161 has an L shape in plan view. Furthermore, in the semiconductor element A1, a plurality of openings 171 are arranged in an L shape at each of the four corners of the wiring layer 14. According to the configuration, the cutouts 161 are formed along the arrangement direction of the openings 171. In other words, each pair of second edges 153 and 154 is formed along a plurality of openings 171 arranged in an L shape. This makes it possible to reduce the area of the wiring layer 14 near the four corners of the obverse-surface electrode 21 in plan view, thus suppressing the thermal stress applied to the wiring layer 14 due to the thermal expansion of the obverse-surface electrode 21. In other words, for the configuration where a plurality of openings 171 are formed in an L shape near each of the four corners of the obverse-surface electrode 21, forming each of the cutouts 161 in an L shape in plan view is preferable in terms of improving the reliability of the semiconductor element A1 on a temperature change.

In the semiconductor element A1, the edge portion 163 of the wiring layer 14 is formed with one or more slits 162. The edge portion 163 can be formed in the wiring layer 14 due to the processing limit in the manufacturing of the semiconductor element A1. Since the wiring layer 14 is arranged in a uniform manner at the edge portion 163, the edge portion 163 is also subjected to the thermal stress due to the thermal expansion of the obverse-surface electrode 21, which may lead to the deformation of the wiring layer 14 at the portions other than the four corners in plan view. To address this issue, the semiconductor element A1 is provided with one or more slits 162, so that the slits 162 (the insulating film 17 filled in the slits 162) restrain the wiring layer 14 to suppress the deformation of the wiring layer 14. In other words, the semiconductor element A1 can suppress the deformation of the wiring layer 14 not only at the four corners of the wiring layer 14 but also across the entire periphery of the wiring layer 14, which makes it possible to further improve reliability on a temperature change.

The semiconductor device B1 includes the semiconductor element A1. The semiconductor device B1 undergoes frequent temperature changes depending on its use environment. For example, when the semiconductor device B1 is mounted on a circuit board of an automobile or the like, the automobile may run under various climatic conditions from cold to hot and humid areas. Furthermore, when the semiconductor device B1 is mounted within the engine room, it will be constantly exposed to temperature changes resulting from the environment and driving patterns. Since the semiconductor element A1 can improve reliability on a temperature change as described above, the semiconductor device B1 has improved reliability on a temperature change. This allows the use of the semiconductor device B1 even in an environment with frequent temperature changes, and the semiconductor device B1 is therefore applicable to a wide range of uses.

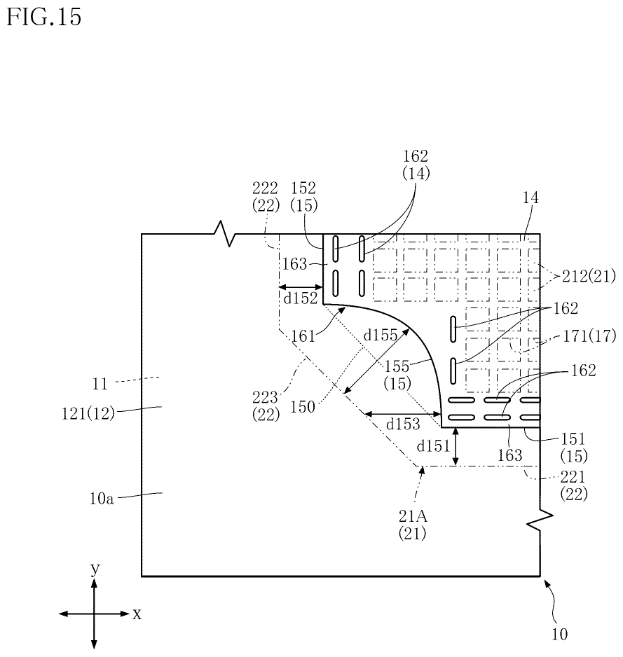

The above embodiment has provided an example where each of the cutouts 161 formed at the four corners of the wiring layer 14 has an L shape in plan view. However, the plan-view shape of the cutouts 161 is not particularly limited as long as the above-described second relationships are satisfied. For example, each of the cutouts 161 may have the shape shown in FIG. 15, and a second edge 155, which is connected to a pair of first edges 151 and 152 at the outer edge 15 of the wiring layer 14, may be curved instead of being linear.

The semiconductor element and the semiconductor device according to the present disclosure are not limited to those in the above embodiment. Various design changes can be made to the specific configurations of the elements of the semiconductor element and the semiconductor device according to the present disclosure. For example, the present disclosure includes the embodiments according to the following clauses.

### Clause 1

A semiconductor element comprising:
an element body including an obverse surface facing one side in a thickness direction;
a wiring layer formed on the obverse surface and electrically connected to the element body; and
an obverse-surface electrode formed on and electrically connected to the wiring layer,
wherein an outer edge of the obverse-surface electrode includes a corner portion as viewed in the thickness direction,
the wiring layer includes a first edge extending along the outer edge of the obverse-surface electrode as viewed in the thickness direction, and a second edge connected to the first edge and facing the corner portion as viewed in the thickness direction, and
the second edge includes a portion that defines, as viewed in the thickness direction, a distance from the second edge to the outer edge of the obverse-surface electrode in a direction perpendicular to the second edge, the distance being greater than a distance from the first edge to the outer edge of the obverse-surface electrode in a direction perpendicular to the first edge.

### Clause 2

The semiconductor element according to clause 1, wherein the outer edge of the obverse-surface electrode includes a side end that is connected to the corner portion and parallel to the first edge, and
the corner portion is linear as viewed in the thickness direction and inclined to the side end as viewed in the thickness direction.

### Clause 3

The semiconductor element according to clause 2, wherein the obverse-surface electrode has an octagonal shape as viewed in the thickness direction.

### Clause 4

The semiconductor element according to clause 2 or 3, wherein the obverse-surface electrode includes a main portion having the corner portion and the side end and overlapping with the wiring layer as viewed in the thickness direction.

### Clause 5

The semiconductor element according to clause 4, further comprising an insulating film interposed between the main portion and the wiring layer in the thickness direction.

### Clause 6

The semiconductor element according to clause 5, wherein the obverse-surface electrode includes a plurality of penetrating portions passing through the insulating film and electrically connecting the main portion and the wiring layer.

### Clause 7

The semiconductor element according to clause 6, wherein the wiring layer includes an edge portion located between the plurality of penetrating portions and the first edge as viewed in the thickness direction, and the edge portion is formed with at least one slit.

### Clause 8

The semiconductor element according to clause 7, wherein the edge portion is formed with a plurality of slits, and the plurality of slits are arranged along the first edge.

### Clause 9

The semiconductor element according to any of clauses 1 to 8, wherein the wiring layer includes an L-shaped cutout having the second edge.

### Clause 10

The semiconductor element according to any of clauses 1 to 9, wherein the wiring layer includes a first layer and a second layer stacked and spaced apart from each other in the thickness direction, and a plurality of vias electrically connecting the first layer and the second layer.

### Clause 11

The semiconductor element according to clause 10, further comprising an interlayer insulating layer located between the first layer and the second layer, and
the plurality of vias pass through the interlayer insulating layer in the thickness direction.

### Clause 12

The semiconductor element according to any of clauses 1 to 11, wherein the wiring layer contains aluminum, and
the obverse-surface electrode contains copper.

### Clause 13

The semiconductor element according to any of clauses 1 to 12, wherein the element body includes a switching circuit and a control circuit.

### Clause 14

The semiconductor element according to clause 13, wherein the obverse-surface electrode includes a first portion and a second portion spaced apart from each other,
the first portion overlaps with the switching circuit as viewed in the thickness direction, and
the second portion overlaps with the control circuit as viewed in the thickness direction.

### Clause 15

The semiconductor element according to clause 13 or 14, further comprising a reverse-surface electrode,
wherein the element body includes a reverse surface facing an opposite side from the obverse surface, and
the reverse-surface electrode is provided on the reverse surface and electrically connected to the switching circuit.

### Clause 16

The semiconductor element according to any of clauses 1 to 15, wherein the element body contains silicon.

### Clause 17

A semiconductor device comprising:
a semiconductor element according to any of clauses 1 to 16;
a die pad portion on which the semiconductor element is mounted;
a sealing resin covering at least a part of the die pad portion and the semiconductor element; and
a terminal portion protruding from the sealing resin and electrically connected to the semiconductor element.

### REFERENCE NUMERALS

A1: Semiconductor element B1: Semiconductor device
10: Element body 10a: Obverse surface
10b: Reverse surface 11: Semiconductor substrate
12: Semiconductor layer 121: Epitaxial layer
13: Interlayer insulating layer 131: First film
132: Second film 133: Third film
134: Fourth film 135: Opening
14: Wiring layer 141: First layer
142: Second layer 143: First via
144: Second via 15: Outer edge
150: Virtual edge 151, 152: First edge
153, 154, 155: Second edge 161: Cutout
162: Slit 163: Edge portion
17: Insulating film 171: Opening
21: Obverse-surface electrode 21A: First portion
21B: Second portion 211: Main portion
212: Penetrating portion 22: Outer edge
221, 222: Side end 223: Corner portion
23: Underlying layer 24: Reverse-surface electrode
25: Pad portion 26: Surface protection film
29: Conductive bonding member 30: Switching circuit
31: Trench gate structure 311: First trench
312: Gate electrode 313: Embedded electrode
361: Second trench 362: Insulator
32: Gate insulating film 33: Body region
34: Source region 35: Body contact region
36: DTI structure 40: Control circuit
51: First lead 511: Die pad portion
511a: Die-pad obverse surface 511b: Die-pad reverse surface
512: Extending portion 52: Second lead
521: Pad portion 522: Terminal portion
61: First connecting member 62: Second connecting member
63: Third connecting member 7: Sealing resin
71: Resin obverse surface 72: Resin reverse surface
73: Resin side surface 74: Resin side surface

1. A semiconductor element comprising:
an element body including an obverse surface facing one side in a thickness direction;
a wiring layer formed on the obverse surface and electrically connected to the element body; and
an obverse-surface electrode formed on and electrically connected to the wiring layer,
wherein an outer edge of the obverse-surface electrode includes a corner portion as viewed in the thickness direction,
the wiring layer includes a first edge extending along the outer edge of the obverse-surface electrode as viewed in the thickness direction, and a second edge connected to the first edge and facing the corner portion as viewed in the thickness direction, and
the second edge includes a portion that defines, as viewed in the thickness direction, a distance from the second edge to the outer edge of the obverse-surface electrode in a direction perpendicular to the second edge, the distance being greater than a distance from the first edge to the outer edge of the obverse-surface electrode in a direction perpendicular to the first edge.

2. The semiconductor element according to claim 1, wherein the outer edge of the obverse-surface electrode includes a side end that is connected to the corner portion and parallel to the first edge, and
the corner portion is linear as viewed in the thickness direction and inclined to the side end as viewed in the thickness direction.

3. The semiconductor element according to claim 2, wherein the obverse-surface electrode has an octagonal shape as viewed in the thickness direction.

4. The semiconductor element according to claim 2, wherein the obverse-surface electrode includes a main portion having the corner portion and the side end and overlapping with the wiring layer as viewed in the thickness direction.

5. The semiconductor element according to claim 4, further comprising an insulating film interposed between the main portion and the wiring layer in the thickness direction.

6. The semiconductor element according to claim 5, wherein the obverse-surface electrode includes a plurality of penetrating portions passing through the insulating film and electrically connecting the main portion and the wiring layer.

7. The semiconductor element according to claim 6, wherein the wiring layer includes an edge portion located between the plurality of penetrating portions and the first edge as viewed in the thickness direction, and
the edge portion is formed with at least one slit.

8. The semiconductor element according to claim 7, wherein the edge portion is formed with a plurality of slits, and
the plurality of slits are arranged along the first edge.

9. The semiconductor element according to claim 1, wherein the wiring layer includes an L-shaped cutout having the second edge.

10. The semiconductor element according to claim 1, wherein the wiring layer includes a first layer and a second layer stacked and spaced apart from each other in the thickness direction, and a plurality of vias electrically connecting the first layer and the second layer.

11. The semiconductor element according to claim 10, further comprising an interlayer insulating layer located between the first layer and the second layer, and
the plurality of vias pass through the interlayer insulating layer in the thickness direction.

12. The semiconductor element according to claim 1, wherein the wiring layer contains aluminum, and
the obverse-surface electrode contains copper.

13. The semiconductor element according to claim 1, wherein the element body includes a switching circuit and a control circuit.

14. The semiconductor element according to claim 13, wherein the obverse-surface electrode includes a first portion and a second portion spaced apart from each other,
the first portion overlaps with the switching circuit as viewed in the thickness direction, and
the second portion overlaps with the control circuit as viewed in the thickness direction.

15. The semiconductor element according to claim 13, further comprising a reverse-surface electrode,
wherein the element body includes a reverse surface facing an opposite side from the obverse surface, and
the reverse-surface electrode is provided on the reverse surface and electrically connected to the switching circuit.

16. The semiconductor element according to claim 1, wherein the element body contains silicon.

17. A semiconductor device comprising:
a semiconductor element according to claim 1;
a die pad portion on which the semiconductor element is mounted;
a sealing resin covering at least a part of the die pad portion and the semiconductor element; and
a terminal portion protruding from the sealing resin and electrically connected to the semiconductor element.
